(19) United States
(12) Patent Application Publication
(10) Pub. No.: US 2010/0236689 A1
(43) Pub. Date: Sep. 23, 2010

(54) ADHESIVE SHEET FOR MANUFACTURING SEMICONDUCTOR DEVICE, AND SEMICONDUCTOR DEVICE MANUFACTURING METHOD USING THE SHEET

(75) Inventors: Yasuhiro Amano, Osaka (JP); Sadahito Misumi, Osaka (JP); Takeshi Matsumura, Osaka (JP); Naohide Takamoto, Osaka (JP)

Correspondence Address: KNOBBE MARTENS OLSON & BEAR LLP, 2040 MAIN STREET, FOURTEENTH FLOOR, IRVINE, CA, 92614, US

(73) Assignee: NITTO DENKO CORPORATION

(21) Appl. No.: 12/675,433

(22) PCT Filed: Aug. 26, 2008
(86) PCT No.: PCT/JP2008/065164

§ 371 Date: Feb. 26, 2010

(30) Foreign Application Priority Data
Aug. 31, 2007 (JP) 2007-226282

(51) Int. Cl. C09J 7/00; B32B 37/12

(52) U.S. Cl. 156/64; 428/221; 524/560; 524/611; 523/400; 156/60

(57) ABSTRACT

The present invention provides an adhesive sheet for manufacturing a semiconductor device, which, even when the adhesive sheet is made thin, makes it possible to easily identify the presence or absence of the adhesive sheet, thereby decreasing down time for the manufacturing apparatus and enabling an improvement of the yield, and to provide a semiconductor device manufacturing method using the sheet. The present invention relates to an adhesive sheet for manufacturing a semiconductor device which is used to adhere a semiconductor element to an adherend, wherein the adhesive sheet contains a pigment which adsorbs or reflects light having a wavelength in a range from 290 to 450 nm.

### TECHNICAL FIELD

The present invention relates to an adhesive sheet for manufacturing a semiconductor device which is used when a semiconductor element is adhered to an adherend such as a lead frame, a TAB film, a substrate, or a separately manufactured semiconductor chip, followed by wire-bonding to the semiconductor device, and to a semiconductor device manufacturing method using the sheet.

### BACKGROUND ART

In a conventional method for manufacturing a semiconductor device, a semiconductor wafer with a pattern formed thereon is diced on each semiconductor chip and then die-bonded on a substrate, a lead frame or other semiconductor chips using a thermal curable paste resin (for example, Patent Document 1 described below). After wire-bonding to semiconductor chips, the semiconductor chips are sealed with a sealing resin to manufacture a semiconductor package.

Also, use of an adhesive sheet using a thermal curable resin and a thermoplastic resin in combination in place of the thermal curable paste resin is proposed (refer to Patent Document 2 and Patent Document 3 described below).

In a conventional method for manufacturing a semiconductor device, for example, a semiconductor wafer is transported between the respective manufacturing processes while detecting the presence or absence of an adhesive sheet adhered to the semiconductor wafer. The detection is specifically performed using an optical sensor capable of detecting light having a wavelength in a range from 290 to 450 nm.

However, as thinning and miniaturization of a semiconductor package progress, the adhesive sheet used for the production becomes thinner. Therefore, it becomes difficult to detect the adhesive sheet using the optical sensor in the respective manufacturing processes. As a result, for example, when the adhesive sheet is laminated with a dicing sheet, lamination may not be performed at a predetermined position, resulting in positional deviation. Also, the adhesive sheet is not sometimes laminated with the dicing sheet at a predetermined position, whereby, only the dicing sheet is transported. As a result, when the adhesive sheet is absent, the semiconductor wafer is transported without being mounted. Even when the semiconductor wafer is mounted, mounting positional deviation of the semiconductor occurs, and therefore the semiconductor wafer is brought into contact with another semiconductor wafer mounted at the predetermined position, and thus the semiconductor wafer may be damaged.

[Patent Document 1] Japanese Unexamined Patent Publication (Kokai) No. 2002-179769

[Patent Document 2] Japanese Unexamined Patent Publication (Kokai) No. 2000-104040

[Patent Document 3] Japanese Unexamined Patent Publication (Kokai) No. 2002-261233

### DISCLOSURE OF THE INVENTION

### Problems to be Solved by the Invention

The present invention has been made in light of the above problems and an object thereof is to provide an adhesive sheet for manufacturing a semiconductor device, which, even when the adhesive sheet is made thin, makes it possible to easily identify the presence or absence of the adhesive sheet, thereby decreasing down time for the manufacturing apparatus and enabling an improvement of the yield, and to provide a semiconductor device manufacturing method using the sheet.

### Means for Solving the Problems

The present inventors have intensively studied about an adhesive sheet for manufacturing a semiconductor device and a semiconductor device manufacturing method using the sheet so as to achieve the above object. As a result, they have found that the above object can be achieved by employing the constitution described below, and thus the present invention has been completed.

That is, in order to solve the above-mentioned problems, the present invention relates to an adhesive sheet for manufacturing a semiconductor device which is used to adhere a semiconductor element to an adherend, wherein the adhesive sheet contains a pigment which adsorbs or reflects light having a wavelength in a range from 290 to 450 nm.

The adhesive sheet for manufacturing a semiconductor device of the present invention (hereinafter may be referred to as an “adhesive sheet”) is composed of a pigment contained therein and the pigment imparts a function capable of absorbing and reflecting light having a wavelength in a range from 290 to 450 nm to the adhesive sheet. Therefore, it becomes possible to easily identify the presence or absence of the adhesive sheet of the present invention as compared with a conventional adhesive sheet. As a result, for example, the occurrence of positional deviation is prevented upon lamination with the dicing sheet or mounting of the semiconductor wafer, and therefore down time for the manufacturing apparatus is decreased and also the yield is improved. In the present invention, the term “adherend” means, for example, a lead frame, a TAB film, a substrate, or a separately manufactured semiconductor chip.

In the above-described constitution, it is also preferable that the content of the pigment is in a range from 0.1 to 1 part by weight based on 100 parts by weight of an adhesive composition constituting the adhesive sheet. Therefore, it becomes possible to improve a transmittance of the adhesive sheet to light having a wavelength in a range from 290 to 450 nm sufficiently enough to easily detect the adhesive sheet.

In the above-described constitution, it is also preferable that the pigment has an average particle diameter in a range from 0.01 to 0.5 μm. The pigment can effectively absorb or reflect light by adjusting an average particle diameter of the pigment to 0.01 μm or more. In contrast, by adjusting the average particle diameter to 0.5 μm or less, the pigment can be uniformly dispersed, and also absorption unevenness and reflection variation can be decreased.

In the above-described constitution, it is also preferable that a transmittance to light having a wavelength in a range from 290 to 450 nm is 40% or less. Thus, since an optical sensor for identification of the adhesive sheet becomes unnecessary and the adhesive sheet is identified more easily, the occurrence of positional deviation upon lamination with a semiconductor wafer, a dicing sheet, or the like can be further prevented.

In the above-described constitution, it is also preferable that the adhesive composition comprises a thermoplastic resin.

In the above-described constitution, it is also preferable that the adhesive composition comprises a thermoplastic resin and a thermosetting resin.

In the above-described constitution, it is also preferable that the thermoplastic resin is an acrylic resin. In the above constitution, the thermal curable resin may be at least one of an epoxy resin or a phenol resin. These resins contain little ionic impurities and have high heat resistance, and therefore can ensure reliability of the semiconductor element.

In the above-described constitution, it is also preferable that a crosslinking agent is added.

In order to solve the above-mentioned problems, the present invention relates to a method for manufacturing a semiconductor device, wherein, when a semiconductor wafer or dicing sheet is laminated with an adhesive sheet for manufacturing a semiconductor device, containing a pigment which adsorbs or reflects light having a wavelength in a range from 290 to 450 nm, the adhesive sheet capable of absorbing or reflecting light having a wavelength in a range from 290 to 450 nm is identified, and lamination is performed while positioning with the semiconductor wafer or the dicing sheet.

According to the manufacturing method of the present invention, since an adhesive sheet containing a pigment capable of absorbing or reflecting light having a wavelength in a range from 290 to 450 nm added therein is used, it becomes easy to identify the adhesive sheet upon lamination with a semiconductor wafer or a dicing sheet, and also the lamination accuracy can be improved. As a result, it is possible to decrease the down time of the manufacturing apparatus and to improve the yield. Also, even when the adhesive sheet is made thin so as to cope with thinning and miniaturization of a semiconductor device, the adhesive sheet can be easily identified without using a special sensor, and thus it becomes possible to manufacture a semiconductor device with suppressing a decrease of the yield.

### BRIEF DESCRIPTION OF THE DRAWINGS

FIG. 1 is a cross-sectional view schematically showing an adhesive sheet according to an embodiment of the present invention, in which FIG. 1(a) shows a case where the adhesive sheet is composed only of an adhesive layer and FIG. 1(b) shows a case where an adhesive layer is provided on a core material.

FIG. 2 is a process chart showing a method for manufacturing a semiconductor device according to an embodiment of the present invention.

FIG. 3 is a cross-sectional schematic view showing a semiconductor device according to another embodiment of the present invention in a state where plural semiconductor elements are three-dimensionally mounted on an adherend.

### EXPLANATION OF REFERENCES

101: Adhesive sheet (Adhesive layer)
102: Core material
103: Adhesive layer
104: Adhesive sheet
201: Circuit board (Adherend)
202: Semiconductor chip (Semiconductor element)
203: Bonding wire
204: Sealing resin
301: First adhesive sheet
302: First semiconductor chip (Semiconductor element)
303: Second adhesive sheet
304: Second semiconductor chip (Semiconductor element)

### BEST MODE FOR CARRYING OUT THE INVENTION

First, an adhesive sheet for manufacturing a semiconductor device of the present invention will be explained below.

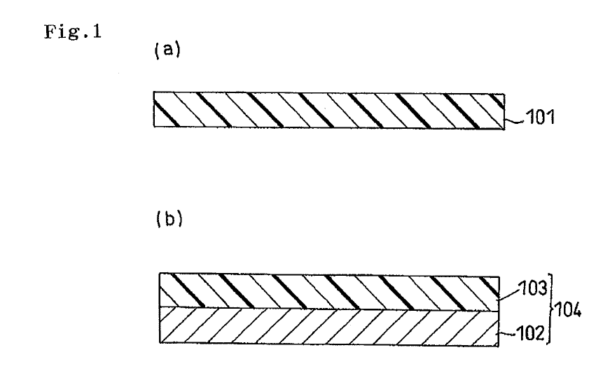

The constitution of the adhesive sheet according to the present invention is not particularly limited as long as the adhesive sheet contains a pigment. For example, an adhesive sheet 101 composed only of a single adhesive layer as shown in FIG. 1(a), an adhesive sheet 104 in which an adhesive layer 103 is laminated on one surface of a core material 102, or an adhesive sheet having a multi-layered structure in which an adhesive layer is formed on both surfaces are exemplified, as shown in FIG. 1(b).

Examples of the core material 102 include films (such as a polyimide film, a polyester film, a polyethylene terephthalate film, a polyethylene naphthalate film, and a polycarbonate film); resin substrates each reinforced with glass fiber or plastic nonwoven fiber; silicon substrates; and glass substrates. Of these core materials, a preferably usable material, which depends on a combination with the constituent material of the adhesive layer, is, for example, a material made of a crosslinked thermoplastic resin. This is because the use of the crosslinked resin causes a fall in the fluidity of the core material. It is allowable to use a material of a type wherein an adhesive sheet is integrated with a dicing sheet.

The pigment is not particularly limited as long as it exhibits poor solubility in water or an organic solvent such as methyl ethyl ketone, and also exhibits light absorption properties or light reflection properties to light having a wavelength in a range from 290 to 450 nm, preferably from 350 to 450 nm, and more preferably from 400 to 430 nm. Specific examples of the pigment include inorganic pigments such as titanium oxide, zinc oxide, talc, sienna, umber, kaolin, calcium carbonate, iron oxide, lamp black, furnace black, ivory black, graphite, fullerene, carbon black, viridian, cobalt blue, emerald green, cobalt green, phthalocyanine green, phthalocyanine blue, Milori blue, fast yellow, disazo yellow, condensed azo yellow, benzoimidazolone yellow, dinitroaniline orange, benzimidazolone orange, perinone orange, toluidine red, permanent carmine, anthraquinonyl red, permanent red, naphthol red, condensed azo red, benzimidazolone carmine, benzimidazolone brown, anthrapyrimidine yellow, quinophthaline yellow, cobalt violet and manganese violet. These inorganic pigments can be used alone, or two or more kinds of them can be used in combination.

The average particle diameter of the pigment is preferably in a range from 0.01 to 0.5 μm, and more preferably from 0.05 to 0.25 μm. When the average particle diameter of the pigment is adjusted within the above numerical value range, it becomes possible to effectively perform light absorption or reflection by the pigment, and also to uniformly disperse the pigment and to decrease absorption unevenness and reflection variation. The average particle diameter of the pigment is a value determined by a laser scattering particle size distribution analyzer (manufactured by Horiba, Ltd. under the trade name of LA-910).

A light transmittance of the adhesive sheet at a light absorption range in a spectral characteristic curve of a visible light range (wavelength range: 290 to 450 nm) is preferably 40% or less, more preferably 30% or less, and particularly preferably 25% or less. When the light transmittance is 40% or less, it becomes easy to identify the adhesive sheet using an optical sensor or the like and thus the occurrence of positional deviation upon lamination with a semiconductor wafer or a dicing sheet is more prevented.

Although there is no particular limitation on the content of the pigment, it is preferred to appropriately set a light transmittance of the adhesive sheet to light in a visible light range to 40% or less taking spectral characteristics of the pigment and spectral characteristics of an adhesive composition (described hereinafter in detail) constituting the adhesive sheet into consideration. Specifically, the content of the pigment is preferably in a range from 0.1 to 1 part by weight, and more preferably from 0.2 to 1 part by weight, based on 100 parts by weight of the adhesive composition. When the content of the pigment is adjusted to 0.1 parts by weight or more, even if the adhesive sheet is identified using an optical sensor, it is possible to exhibit spectral characteristics suited for the optical sensor. In contrast, when the content is 1 part by weight or less, it is possible to suppress a cohesive strength of the adhesive sheet from increasing too much. For example, it is possible to prevent deterioration of expanding properties with preventing fracture upon expanding. It is also possible to improve peeling properties to the dicing sheet upon picking up.

The method of dispersing a pigment in an adhesive composition as a constituent material of the adhesive sheet is not particularly limited, and various conventionally known methods can be employed. Specifically, an adhesive composition and a predetermined solvent are mixed and the obtained mixture is kneaded and dispersed together with the pigment using a pigment disperser such as three-roll mill, ball mill or sand mill. Subsequently, the pigment having a particle diameter of a predetermined value or more may be removed by filtering using a centrifugal separator, a glass filter or a membrane filter to manufacture the constituent material of the adhesive sheet. The pigment is sufficiently dispersed in the same manner as described above by mixing the adhesive composition with a solution of a compatible binder resin. Then, the pigment having a particle diameter of a predetermined value or more is removed by filtration as described above to manufacture a colorant. The constituent material of the adhesive sheet may also be manufactured by mixing the colorant with the adhesive composition. When the pigment having a particle diameter of a predetermined value or more is removed from the adhesive composition or the colorant containing the pigment dispersed therein, the viscosity of the adhesive composition or the colorant is preferably adjusted to 1,500 Pa·s or less, more preferably 400 to 1,200 Pa·s, and particularly 600 to 1,000 Pa·s. When the viscosity is adjusted to 1,500 Pa·s or less, it becomes possible to improve dispersibility of the pigment and to make light absorption or reflection properties inside the surface of the adhesive sheet uniform.

A shear adhesive strength in a state where an adhesive sheet (an adhesive layer when the adhesive layer is laminated on a core material) is adhered to an adherend followed by heating to 175° C. is preferably from 0.2 to 2 MPa, and more preferably froM 0.4 to 1.6 MPa. When the shear adhesive strength of the adhesive sheet is adjusted to 0.2 MPa or more, even if a wire bonding step (described hereinafter) is performed, the occurrence of shear deformation at the adhesive surface between the adhesive sheet, the semiconductor element and the adherend can be further suppressed by supersonic vibration and heating in this step. In other words, movement of the semiconductor element is suppressed by supersonic vibration upon wire bonding, thereby preventing a decrease in a success rate of wire bonding. In the sealing step, it is possible to prevent the semiconductor element from flowing due to pressure. When the shear adhesive strength exceeds 2 MPa, it may become difficult to pick up a semiconductor chip (a semiconductor element) in a picking up step because of too strong adhesive strength. The shear adhesive strength can be adjusted by appropriately adjusting the amount of the epoxy resin and the phenol resin to be mixed with an organic resin composition in the adhesive sheet.

The adhesive sheet (in a case where the adhesive sheet is a sheet wherein an adhesive layer is laminated on a core material, the adhesive layer) preferably has elasticity in some measure at least in the direction perpendicular to the in-plane direction from the viewpoint of the adhesive function of the sheet. In the meantime, in a case where the adhesive sheet has elasticity excessively as a whole, sufficient fixation of a lead frame to which the adhesive sheet is attached is hindered by elastic force of the adhesive sheet even when bonding wires are connected at the time of wire bonding. As a result, compression energy based on pressure-application is relieved so that a bonding failure is generated. In the wire bonding step, the bonding is performed under a high temperature condition of about 150° C. to 200° C. temperature. It is therefore preferred that the tensile storage elasticity at 120° C. before the adhesive sheet is cured is 1×10⁴ Pa or more, more preferably from 0.1 to 20 MPa. If the tensile storage elasticity is less than 1×10⁴ Pa, the adhesive sheet melted when the semiconductor is diced is bonded to, for example, chips of the semiconductor. As a result, the chips may not be picked up with ease. The tensile storage elasticity at 200° C. after the adhesive sheet is cured is preferably 50 MPa or less, more preferably from 0.5 to 40 MPa. If the elasticity is more than 50 MPa, the embeddable property of the adhesive sheet to an uneven face may be declined at the time of molding after the wire bonding. When the elasticity is set to 0.5 MPa or more, stable wire connection can be attained in a semiconductor device characterized by having a leadless structure. The tensile storage elasticity can be adjusted by adjusting the added amount of the lamellar silicate or an inorganic filler, which will be described later, appropriately. A method for measuring the tensile storage elasticity will be described later.

A thickness (a total thickness in the case of a laminated sheet) of the adhesive sheet is preferably in a range from 5 to 100 μm, and more preferably from 5 to 70 μm. In the present invention, even when the adhesive sheet is made thin so as to cope with thinning and miniaturization of a semiconductor device, the adhesive sheet can be identified without requiring a special sensor, and thus the occurrence of positional deviation can be prevented.

The above-mentioned adhesive layer is a layer having an adhesive function. The constituent material thereof may be a material wherein a thermoplastic resin and a thermosetting resistance are used together. A thermoplastic resin alone may be used.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, acrylic resin, saturated polyester resins such as PET and PBT, polyamideimide resin, and fluorine-contained resin. These thermoplastic resins may be used alone or in combination of two or more thereof. Of these thermoplastic resins, acrylic resin is particularly preferable since the resin contains ionic impurities in only a small amount and has a high heat resistance so as to make it possible to ensure the reliability of the semiconductor element.

The acrylic resin is not limited to any especial kind, and may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

A different monomer which constitutes the above-mentioned polymer is not limited to any especial kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl) methylacrylate; monomers which contain a sulfonic acid group, such as styrenesulfonic acid, allylsulfonic acid, 2-(meth)acrylamide-2-methylpropanesulfonic acid, (meth) acrylamidepropane sulfonic acid, sulfopropyl (meth)acrylate, and (meth)acryloyloxynaphthalenesulfonic acid; and monomers which contain a phosphoric acid group, such as 2-hydroxyethylacryloyl phosphate.

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly(p-oxystyrene). These may be used alone or in combination of two or more thereof. Among these phenol resins, phenol Novolak resin and phenol aralkyl resin are particularly preferable, since the connection reliability of the semiconductor device can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

In the present invention, an adhesive sheet comprising the epoxy resin, the phenol resin, and an acrylic resin is particularly preferable. Since these resins contain ionic impurities in only a small amount and have high heat resistance, the reliability of the semiconductor element can be ensured. About the blend ratio in this case, the amount of the mixture of the epoxy resin and the phenol resin is from 10 to 200 parts by weight for 100 parts by weight of the acrylic resin component.

In order to crosslink the adhesive sheet of the present invention to some extent in advance, it is preferable to add, as a crosslinking agent, a polyfunctional compound which reacts with functional groups of molecular chain terminals of the above-mentioned polymer to the materials used when the sheet is produced. In this way, the adhesive property of the sheet at high temperatures is improved so as to improve the heat resistance.

The crosslinking agent may be one known in the prior art. Particularly preferable are polyisocyanate compounds, such as tolylene diisocyanate, diphenylmethane diisocyanate, p-phenylene diisocyanate, 1,5-naphthalene diisocyanate, and adducts of polyhydric alcohol and diisocyanate. The amount of the crosslinking agent to be added is preferably set to 0.05 to 7 parts by weight for 100 parts by weight of the above-mentioned polymer. If the amount of the crosslinking agent to be added is more than 7 parts by weight, the adhesive force is unfavorably lowered. On the other hand, if the adding amount is less than 0.05 part by weight, the cohesive force is unfavorably insufficient. A different polyfunctional compound, such as an epoxy resin, together with the polyisocyanate compound may be incorporated if necessary.

An inorganic filler may be appropriately incorporated into the adhesive sheet of the present invention in accordance with the use purpose thereof. The incorporation of the inorganic filler makes it possible to confer electric conductance to the sheet, improve the thermal conductivity thereof, and adjust the elasticity. Examples of the inorganic fillers include various inorganic powders made of the following: a ceramic such as silica, clay, plaster, calcium carbonate, barium sulfate, aluminum oxide, beryllium oxide, silicon carbide or silicon nitride; a metal such as aluminum, copper, silver, gold, nickel, chromium, lead, tin, zinc, palladium or solder, or an alloy thereof; and carbon. These may be used alone or in combination of two or more thereof. Among these, silica, in particular fused silica is preferably used. The average particle size of the inorganic filler is preferably from 0.1 to 80 μm.

The amount of the inorganic filler to be incorporated is preferably set into the range of 0 to 80 parts by weight (more preferably, 0 to 70 parts by weight) for 100 parts by weight of the organic resin components.

If necessary, other additives besides the inorganic filler may be incorporated into the adhesive sheet of the present invention. Examples thereof include a flame retardant, a silane coupling agent, and an ion trapping agent.

Examples of the flame retardant include antimony trioxide, antimony pentaoxide, and brominated epoxy resin. These may be used alone or in combination of two or more thereof.

Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof.

Examples of the ion trapping agent include hydrotalcite and bismuth hydroxide. These may be used alone or in combination of two or more thereof.

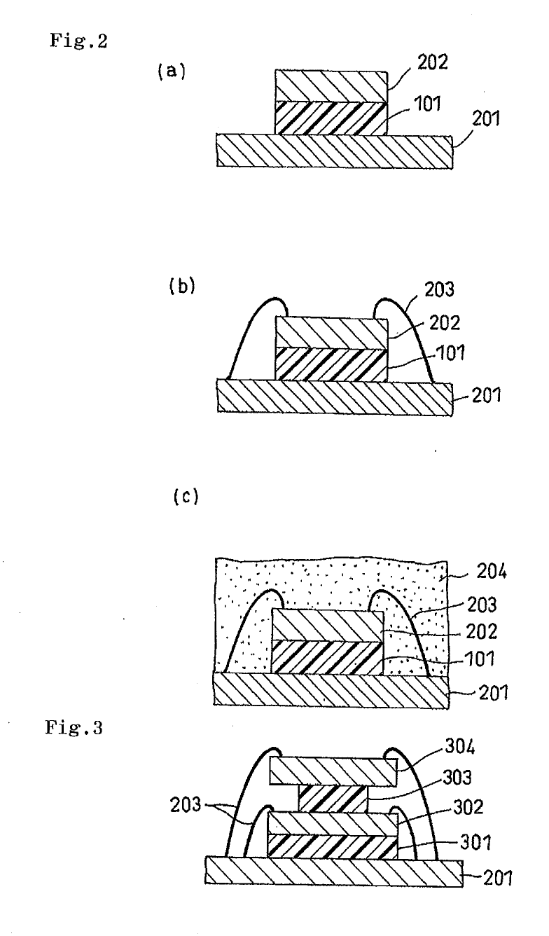

With reference to FIGS. 2 and 3, the following will describe a method for producing a semiconductor device using the adhesive sheet 101.

First, the adhesive sheet 101 is laminated on a pressure-sensitive adhesive layer of a dicing sheet. The dicing sheet is not particularly limited and a conventionally known dicing sheet can be used. In the present embodiment, a dicing sheet comprising a base material layer and a pressure-sensitive adhesive layer laminated on the base material layer is used.

Lamination is performed using an optical sensor capable of identifying the adhesive sheet 101 while positioning the adhesive sheet 101 with the dicing sheet. Since a transmittance of the adhesive sheet 101 to light having a wavelength in a range from 290 to 400 nm is 40% or less, it is possible to easily identify without disposing a special sensor. The optical sensor is not particularly limited as long as it can detect light having a wavelength in a range from 290 to 400 nm.

Next, a semiconductor wafer is compression-bonded on the adhesive sheet 101, followed by fixation while adhering and holding (mounting step). The present step is performed while pressing by an extrusion means such as a compression bonding roll. Also in the present step, the semiconductor wafer is mounted at a predetermined position while positioning using an optical sensor capable of identifying the position of the adhesive sheet.

Next, dicing of the semiconductor wafer is performed. The semiconductor wafer is cut into pieces each having a predetermined size to form a semiconductor chip 202. Dicing is performed from a circuit side surface of the semiconductor wafer according to a conventional method. Also in the present step, a cutting method called as full cutting of cutting to the pressure-sensitive adhesive layer in the dicing sheet can be employed. A dicing apparatus used in the present step is not particularly limited and a conventionally known dicing apparatus can be used. Since the semiconductor wafer is adhered and fixed by the adhesive sheet 101, chipping and chip scattering can be suppressed and also breakage of the semiconductor wafer can be suppressed.

Subsequently, the semiconductor chip 202 is picked up so as to peel the semiconductor chip 202 adhered and fixed to the adhesive sheet 101. A picking up method is not particularly limited and various conventionally known methods can be employed. For example, a method of pushing up each semiconductor chip 202 by a needle from the dicing sheet side and picking up the pushed-up semiconductor chip 202 by a pickup apparatus.

The semiconductor chip is picked up after irradiating the pressure-sensitive adhesive layer with ultraviolet rays when the pressure-sensitive adhesive layer is ultraviolet-ray curing-type. Therefore, an adhesive strength of the pressure-sensitive adhesive layer to the adhesive sheet 101 decreases and it becomes easy to peel the semiconductor chip 202. As a result, it becomes possible to pick up without damaging the semiconductor chip. The conditions such as irradiation intensity and irradiation time upon irradiation with ultraviolet rays are not particularly limited and may be appropriately set, if necessary. As a light source used for irradiation with ultraviolet rays, those described above can be used.

The picked-up semiconductor chip 202 is adhered and fixed to an adherend 201 via the adhesive sheet 101 (die bond). Examples of the adherend 201 include a lead frame, a TAB film, a substrate, and a separately manufactured semiconductor chip. The adherend 201 may be a deformable adherend which is easily deformed, or a non-deformable adherend which is hardly deformed (a semiconductor wafer and the like)

The substrate may be any substrate known in the prior art. The lead frame may be a metal lead frame such as a Cu lead frame or a 42-alloy lead frame; or an organic substrate made of glass epoxy resin, BT (bismaleimide-triazine), polyimide or the like. In the present invention, however, the substrate is not limited to these substrates, and may be a circuit substrate that can be used in the state that a semiconductor element is mounted on the substrate itself and is electrically connected thereto.

When the adhesive sheet 101 is thermal curing-type, the semiconductor chip 202 is adhered and fixed to the adherend 201 thereby increasing heat resisting strength.

The die bond may be merely fixed temporarily to the adherend 201 without curing the adhesive sheet 101. Thereafter, wire bonding is performed without performing a heating step, and the semiconductor chip can be sealed with a sealing resin, followed by after curing of the sealing resin.

In this case, it is preferred to use the adhesive sheet 101 in which a shear adhesive strength upon temporary fixation to the adherend is 0.2 MPa or more, and more preferably from 0.2 to 10 MPa. When the shear adhesive strength of the adhesive sheet 101 is 0.2 MPa or more, even if a wire bonding step is performed without performing the heating step, shear deformation does not occur at the adhesive surface between the adhesive sheet 101, the semiconductor chip 202 or the adherend 201 by supersonic vibration and heating in this step. In other words, supersonic vibration upon wire bonding does not cause movement of the semiconductor element, and thus a decrease in a success rate of wire bonding is prevented.

The wire bonding step is a step of electrically connecting the tips of terminal portions (inner leads) of the adherend 201 to electrode pads (not illustrated) on the semiconductor chip through bonding wires 203 (see FIG. 3). As the bonding wires 203, for example, gold wires, aluminum wires or copper wires are used. When the wire bonding is performed, the bonding temperature is indispensably from 80 to 250° C., preferably from 80 to 220° C. The heating time is from several seconds to several minutes. The wire-connection is attained by use of both of vibration energy based on ultrasonic waves and compression energy based on the application of pressure in the state that the workpiece is heated to a temperature in the above-mentioned range.

The present step can be performed without fixing with the adhesive sheet 101. During the process of the present step, the semiconductor chip 202 is not fixed to the adherend 201 by the adhesive sheet 101.

The above-mentioned sealing step is a step of sealing the semiconductor chip 202 with a sealing resin 204 (see FIG. 3), and is performed to protect the semiconductor chip 202 and the bonding wires 203 mounted on the adherend 201. The present step is performed by molding the sealing resin with a mold or die. The sealing resin 204 may be, for example, an epoxy resin. The heating for the resin-sealing is performed usually at 175° C. for 60 to 90 seconds. In the this invention, however, the heating is not limited to this, and may be performed, for example at 165 to 185° C. for several minutes. In the present step, the application of pressure may be performed at the time of the resin-sealing. In this case, the pressure to be applied is preferably from 1 to 15 MPa, more preferably from 3 to 10 MPa. When the pressure in the range is applied, the semiconductor chip 202 and the adherend 201 can be bonded to each other interposed the adhesive sheet 101 therebetween and further a gap present therebetween can be stuffed. As a result, the bonding through the adhesive sheet 101 can be attained in the present step even if an after-curing step, which will be descried later, is not performed. Thus, the pressure-application can contribute to a decrease in the number of the producing steps and a reduction in the period for the semiconductor-device-production.

In the above curing step, a sealing resin 204, which is not completely cured in the above sealing step, is completely cured. Even if fixation is not performed by the adhesive sheet 101 in the sealing step, it becomes possible to cure the sealing resin 204 and to fix by the adhesive sheet 101 in the present step. The heating temperature in the present step varies depending on the kind of the sealing resin and is, for example, in a range from 165 to 185° C., and the heating time is from about 0.5 to 8 hours.

A dicing-die bond film of the present invention can also be preferably used when a plurality of semiconductor chips are three-dimensionally mounted by lamination, as shown in FIG. 3. FIG. 3 is a schematic cross-sectional view showing an example in which semiconductor chips are three-dimensionally mounted via an adhesive sheet. In the case of three-dimensional mounting shown in FIG. 3, first, at least one first adhesive sheet 301 cut so as to have the same size as that of the semiconductor chip is temporarily fixed on an adherend 201, and then a first adhesive sheet 302 is temporarily fixed via the first adhesive sheet 301 so that the wire bond surface faces upward. Next, a second adhesive sheet 303 is temporarily fixed while avoiding an electrode pad portion of the first semiconductor chip 302. Furthermore, a second semiconductor chip 304 is temporarily fixed on the second adhesive sheet 303 so that the wire bond surface faces upward.

Next, a wire bonding step is performed without performing a heating step. In this step, each electrode pad in the first semiconductor chip 302 and the second semiconductor chip 304 is electrically connected to an adherend 201 using a bonding wire 203.

Subsequently, a sealing step of sealing a semiconductor chip with a sealing resin is performed and the sealing resin is cured. Simultaneously, the adhered 201 and the first semiconductor chip 302 are fixed together by the first adhesive sheet 301. Also, the first semiconductor chip 302 and the second semiconductor chip 304 are fixed together by the second adhesive sheet 303. After the sealing step, a post-curing step may be performed.

Since a heating treatment by heating of the first adhesive sheet 301 and the second adhesive sheet 303 is not performed in three-dimensional mounting of the semiconductor chip, simplification of the manufacturing process and improvement of the yield can be performed. Since neither warp of the adherend 201 nor crack of the first semiconductor chip 302 and the second semiconductor chip 304 occurs, it becomes possible to make a single layer of the semiconductor element thin.

### (Other Matters)

When a semiconductor element is three-dimensionally mounted on the substrate, a buffer coat film is formed on the surface side on which a circuit of the semiconductor element is formed. The buffer coat layer includes, for example, a silicon nitride film or those made of a heat-resistant resin such as a polyimide resin.

When the semiconductor element is three-dimensionally mounted, the adhesive sheet used in each stage is not limited to those with the same composition and can be appropriately changed according to manufacturing conditions and uses.

While an aspect of performing a wire bonding step collectively after laminating a plurality of semiconductor elements on a substrate in the above embodiment, the present invention is not limited thereto. For example, a wire bonding step can also be performed every time the semiconductor element is laminated on the substrate.

### EXAMPLES

Preferred examples of this invention will be illustratively described in detail hereinafter. However, materials, blend amounts and others that will be described in the Examples do not limit to this invention unless any restrictive description is particularly included. Thus, these are mere explanatory examples. In the examples, the word “part(s)” represent “part(s) by weight”, respectively, unless otherwise specified.

### Example 1

First, 100 parts of a polymer containing butyl acrylate as a main component (manufactured by Negami Chemical industrial Co., Ltd. under the trade name of PARACRON SN-710), 3 parts of an isocyanate-based crosslinking agent (manufactured by NIPPON POLYURETHANE INDUSTRIES Co., Ltd. under the trade name of Coronate HX), 33 parts of an epoxy resin (manufactured by Japan Epoxy Resins CO., LTD. under the trade name of EPICOAT 1003), 22 parts of a phenol resin (manufactured by ARAKAWA CHEMICAL INDUSTRIES, LTD. under the trade name of P-180) and 0.2 parts of ultrafine titanium oxide particles (manufactured by Titan Kogyo, Ltd. under the trade name of STT-4D, average particle diameter: 0.15 μm) were dissolved in methyl ethyl ketone, followed by stirring to prepare a solution of an adhesive composition (concentration: 15% by weight).

The adhesive composition solution was kneaded and dispersed by a three-roll mill, centrifuged at 400 ppm and then filtered through a glass filter having a pore diameter of 0.7 μm.

Next, filtered adhesive composition solution was applied on a film subjected to a mold-release treatment (core material) composed of a polyethylene terephthalate film (thickness: 50 μm) subjected to a silicone mold-release treatment and then dried at 120° C. for 2 minutes. Thus, an adhesive sheet comprising a mold-release treated film and an adhesive layer having a thickness of 7 μm laminated on the mold-release treated film according to Example 1 of the present invention was manufactured.

### Example 2

To 100 parts of an acryl-based adhesive, 3 parts of an isocyanate-based crosslinking agent (manufactured by NIPPON POLYURETHANE INDUSTRIES Co., Ltd. under the trade name of Coronate HX) was added to prepare an acryl-based adhesive composition. The acryl-based adhesive composition was obtained by mixing 70 parts of 2-ethylhexyl acrylate, 25 parts of n-butyl acrylate and 5 parts of acrylic acid to prepare an acryl-based copolymer composed of these monomers, and dissolving the acryl-based copolymer and 1 part of Fastgen blue GNPS (manufactured by Dainippon Ink and Chemicals, Incorporated, blue pigment: copper phthalocyanine-based pigment, average particle diameter: 0.1 μm) in methyl ethyl ketone in a concentration of 15%.

In the same manner as in Example 1, centrifugation was performed and then filtration was performed to manufacture an adhesive sheet comprising a mold-release treated film and an adhesive layer having a thickness of 7 μm laminated on the mold-release treated film.

### Comparative Example 1

In the same manner as in Example 1, except that a pigment was not added in the case of preparing an adhesive composition, an adhesive sheet according to Comparative Example 1 was manufactured.

### (Results)

With respect to the adhesive sheets of Examples 1 and 2, and Comparative Example 1, tensile storage elastic modulus, shear adhesive strength, dicing properties and moisture absorption reliability were evaluated by the following procedures. The results are as shown in Table 1.

### [Method for Measurement of Transmittance]

With respect to the adhesive sheets manufactured in the above Examples and Comparative Example, a transmittance to light having a wavelength of 400 nm was measured as follows. Each transmission was determined by measuring ultraviolet-visible-near infrared absorption spectra at a scan speed of 300 nm/min using U-3310 (trade name) manufactured by Hitachi High-Technologies Corporation. The results are shown in Table 1 below.

[Transportation Properties using Automatic Laminating Machine]

With respect to the adhesive sheets manufactured in the above Examples and Comparative Example, the number of troubles in the case of mounting 100 semiconductor wafers was measured. DR-8500II (trade name) manufactured by NITTO SEIKI CO., LTD. was used as a mount. Regarding the number of troubles, the case of the occurrence of positional deviation (the semiconductor wafer is not mounted at a laminating position on the adhesive sheet) and the device being temporarily stopped was observed. The results are shown in Table 1 below.

### [Evaluation of Pickup Properties]

A dicing tape (manufactured by NITTO DENKO CORPORATIION under the trade name of DU-300) was laminated on each of the adhesive sheets obtained in the above Examples and Comparative Example at a laminating temperature of 40° C. and a linear pressure of 4 kgf/cm, followed by lamination to a back surface of a semiconductor wafer (diameter: 8 inch, thickness: 100 μm) at 50° C. Next, the obtained laminate was diced into a size of a semiconductor chip measuring 5 mm×5 mm at a spindle revolving speed of 40,000 rpm and a cutting speed of 50 mm/sec using a dicer.

Next, the semiconductor chip manufactured by dicing was picked up using a die bonder (manufactured by SHINKAWA LTD. under the trade name of SPA-300) and pickup properties were evaluated. Specifically, 100 semiconductor chips were picked up and a success rate (%) was calculated by counting the number of success.

### [Evaluation of Moisture Absorption Reliability]

The above semiconductor chip was die-bonded to a bismaleimide-triazine resin substrate under the conditions of 120° C. under 500 gf for 1 second. After applying heat history at 180° C. for 1 hour, molding was performed by an epoxy-based sealing resin (manufactured by NITTO SEIKI CO., LTD. under the trade name of HC-300B6) at 175° C. (preheat setting time: 3 seconds, injection time: 12 seconds, curing time: 120 seconds) using a molding machine (manufactured by TOWA CORPORATION under the trade name of Model-Y-series). Furthermore, thermal curing was performed under the conditions of 175° C. for 5 hours to obtain a semiconductor package.

The obtained semiconductor package was subjected to a moisture absorption treatment under the environment of a temperature of 30° C. and a relative humidity of 60% RH for 192 hours using a thermohygrostat. Next, the semiconductor package was repeatedly introduced in an IR reflow apparatus SAI-2604M (manufactured by Senju Metal Industry Co., Ltd.) three times. A package surface peak temperature was adjusted to 260° C. After cutting the center portion of the package, a cut surface was polished and a cross section of the package was observed using a KEYENCE type optical microscope. The semiconductor package where peeling of the adhesive sheet was not recognized in the cross section of the package was rated “Good”, whereas the semiconductor package where peeling of the adhesive sheet was recognized was rated “Poor”.

TABLE 1

| | | Examples | Comparative |
|---|---|---|---|
| | Examples 1 | 2 | Example 1 |
| Transmittance to light having a | 24.1 | 20.4 | 41.6 |
| wavelength of 400 nm | | | |
| Number of troubles in automatic | 0/100 | 0/100 | 32/100 |
| laminating machine (times/100) | | | |
| Pickup success rate (%) | 100 | 100 | 100 |
| Moisture absorption reliability | Good | Good | Poor |
| (presence or absence of peeling) | | | |

As is apparent from Table 1, the adhesive sheets of Examples 1 and 2 of the present invention enabled improvement of the yield upon mounting of the semiconductor wafer, and exhibited satisfactory transportation properties. The adhesive sheets were also excellent in pickup properties and moisture absorption reliability. The adhesive sheets of Examples 1 and 2 contained a pigment, and thus making it possible to identify without requiring a special sensor for identifying the adhesive sheet, and to decrease down time for an automatic laminating machine. Furthermore, it became possible to prevent cracking of the semiconductor wafer due to defective mounting and to improve productivity of the semiconductor package. In contrast, in a conventional adhesive sheet made of an acrylic resin shown in Comparative Example 1, positional deviation upon mounting of the semiconductor wafer occurred, resulting in transportation trouble and defective peeling.

1. An adhesive sheet for manufacturing a semiconductor device which is used to adhere a semiconductor element to an adherend, wherein the adhesive sheet contains a pigment which adsorbs or reflects light having a wavelength in a range from 290 to 450 nm.

2. The adhesive sheet for manufacturing a semiconductor device according to claim 1, wherein the content of the pigment is in a range from 0.1 to 1 part by weight based on 100 parts by weight of an adhesive composition constituting the adhesive sheet.

3. The adhesive sheet for manufacturing a semiconductor device according to claim 1, wherein the pigment has an average particle diameter in a range from 0.01 to 0.5 μm.

4. The adhesive sheet for manufacturing a semiconductor device according to claim 1, wherein a transmittance to light having a wavelength in a range from 290 to 450 nm is 40% or less.

5. The adhesive sheet for manufacturing a semiconductor device according to claim 2, wherein the adhesive composition comprises a thermoplastic resin.

6. The adhesive sheet for manufacturing a semiconductor device according to claim 2, wherein the adhesive composition comprises a thermoplastic resin and a thermosetting resin.

7. The adhesive sheet for manufacturing a semiconductor device according to claim 5, wherein the thermoplastic resin is an acrylic resin.

8. The adhesive sheet for manufacturing a semiconductor device according to claim 6, wherein the thermoplastic resin is an acrylic resin.

9. The adhesive sheet for manufacturing a semiconductor device according to claim 6, wherein the thermosetting resin is at least either an epoxy resin or a phenol resin.

10. The adhesive sheet for manufacturing a semiconductor device according to claim 6, to which a crosslinking agent is added.

11. A method for manufacturing a semiconductor device, wherein, when a semiconductor wafer or dicing sheet is laminated with an adhesive sheet for manufacturing a semiconductor device, containing a pigment which adsorbs or reflects light having a wavelength in a range from 290 to 450 nm, the adhesive sheet capable of absorbing or reflecting light having a wavelength in a range from 290 to 450 nm is identified, and lamination is performed while positioning with the semiconductor wafer or the dicing sheet.

12. The adhesive sheet for manufacturing a semiconductor device according to claim 1, wherein a shear adhesive strength of the adhesive sheet upon temporary fixation of the adhesive sheet to an adherend is from 0.2 to 10 MPa.

13. The adhesive sheet for manufacturing a semiconductor device according to claim 1, wherein tensile storage elasticity at 120° C. before the adhesive sheet is cured is from 0.1 to 20 MPa.

14. The adhesive sheet for manufacturing a semiconductor device according to claim 13, wherein the tensile storage elasticity at 200° C. after the adhesive sheet is cured is from 0.5 to 40 MPa.

15. A method for manufacturing a semiconductor device, comprising:
laminating the adhesive sheet of claim 1 onto a pressure-sensitive adhesive layer of a dicing sheet by positioning the adhesive sheet using an optical sensor capable of identifying the adhesive sheet, wherein the dicing sheet comprises a pressure-sensitive adhesive layer and a base material layer; and
compression-bonding a semiconductor wafer onto the adhesive sheet by positioning the semiconductor wafer using an optical sensor capable of identifying the adhesive sheet.
